(19) United States
(12) Patent Application Publication
(10) Pub. No.: US 2009/0190035 A1
(43) Pub. Date: Jul. 30, 2009

(54) CIRCUIT FOR PROCESSING VIDEO SIGNAL

(76) Inventor: Chao-Hsin Lu, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 12/021,310

(22) Filed: Jan. 29, 2008

(51) Int. Cl. H03M 1/12; H04N 5/14

(52) U.S. Cl. 348/571; 348/572; 348/E05.062

(57) ABSTRACT

Disclosed is a video signal processing circuit, which comprises: first and second DC level adjusting circuits, for adjusting the DC level of a video signal to generate a first adjusted video signal and a second adjusted video signal respectively; an analog to digital converter, for sampling a data signal of the video signal according to a target clock signal; a sync signal separating circuit, for separating a sync signal from the first adjusted video signal; a sync signal processor, for detecting the existence of the sync signal, and outputting a sync clock signal if the sync signal exists; a multiplexer, for outputting one of the sync clock signal or predetermined clock signal as the target clock signal according to a selecting signal; and a processor unit, for controlling the first DC level adjusting circuit, the second DC level adjusting circuit, and for generating the selecting signal.

### BACKGROUND OF THE INVENTION

1. Field of the Invention

The present invention relates to a video signal processing circuit, but more particularly, to a video signal processing circuit that utilizes a single pin of an integrated circuit to receive a video signal

2. Description of the Prior Art

FIG. 1 is a block diagram illustrating a transmitting path 100 for transmission of a video signal. As shown in FIG. 1, the transmitting path 100 comprises a display transmitter 101, a connection block 103, a video IC, and capacitors 107, 109, 111, and 113, wherein the video IC further includes 4 pins: 115, 117, 119 and 121. The display transmitter 101 is used for receiving a video signal VS, separating the video signal VS into R,G,B signals and then transmitting the R,G,B signals to the connection block 103 of a printed circuit board. As known to those in the related art, the connection block 103 can include a connector, a noise reducing circuit, and a resistor used for transmitting the R,G,B signals to the video IC 105, wherein the G signal (or Y signal) is separated into two signals to enter the capacitors 107, 109 and pins 115, 117, respectively.

FIG. 2 is a related art video signal processing circuit 200 located within the video IC 105 as shown in FIG. 1. As shown in FIG. 2, the video signal processing circuit 200 comprises: capacitors 201, 203 for filtering noise of the video signal, pads 205, 207, a first DC level adjusting circuit 209, a second DC level adjusting circuit 211, a buffer 213, an analog to digital converter 215, a sync signal separating circuit 217, a sync signal processor 219 and a processor unit 221. Capacitances 201, 203 are used for filtering noise of the video signal. Pads 205, 207 are used as terminals to receive the video signal. The first DC level adjusting circuit 209 is used for adjusting the DC voltage level of the video signal to a voltage level A, that is, the lowest possible level of the video signal. The second DC level adjusting circuit 211 is used for adjusting the DC voltage level of the video signal to a voltage level B, that is, a blanking level. It should be noted that the first DC level adjusting circuit 209 and the second DC level adjusting circuit 211 are sometimes named clamping circuits. The buffer 213 is used for buffering the video signal to be sampled by the analog to digital converter 215. The analog to digital converter 215 is used for sampling the video signal according to clock signal CLK-SYNC to generate a sampling result SR. The sync signal separating circuit 217 is used for separating the sync signal from the video signal to general a sync signal SYNC. The sync signal processor 219 is used for detecting the existence of the sync signal SYNC to inform the processor unit 221 the existence of the sync signal SYNC, and for generating the clock signal CLK-SYNC according to the sync signal SYNC. The processor unit 221 is used for controlling the first DC level adjusting circuit 209 and the second DC level adjusting circuit 211 according to the sampling result SR, and the clock signal CLK-SYNC. In brief, the video signal is received by the two pads and are processed by group A: first DC level adjusting circuit 209, sync signal separating circuit 217, a sync signal processor 219. Group B, which includes: a second DC level adjusting circuit 211, the buffer 213, and the analog to digital converter 215 acts independently.

The above mentioned video signal processing circuit 200 therefore needs two pads and two capacitances. This however, increases the cost of manufacture and reduces usable area of the circuit. The versatility of the video IC is also reduced since two pins of the video IC are occupied for this task. Therefore, a new invention is required to solve these problems.

### SUMMARY OF THE INVENTION

Therefore, one objective of the present invention is to provide a video signal processing circuit requiring only one pad and one capacitor.

The present invention discloses a video signal processing circuit for processing a video signal with a data signal higher than a blanking level and a sync signal lower than the blanking level. The video processing circuit comprises: a first DC level adjusting circuit, coupled to the video signal, for adjusting a DC level of the video signal to generate a first adjusted video signal; a second DC level adjusting circuit, coupled to the video signal, for adjusting a DC level of the video signal to generate a second adjusted video signal; an analog to digital converter, coupled to the second DC level adjusting circuit, for sampling the data signal according to the second adjusted video signal and a target clock signal; a sync signal separating circuit, coupled to the first DC level adjusting circuit, for separating the sync signal from the first adjusted video signal; a sync signal processor, coupled to the sync signal separating circuit, for detecting an existence of the sync signal, and outputting a sync clock signal according to the sync signal if the sync signal processor detects the existence of the sync signal; a multiplexer, coupled to the analog to digital converter and the sync signal processor, for outputting one of the sync clock signal or a predetermined clock signal as the target clock signal according to a selecting signal; and a processor unit, coupled to the first DC level adjusting circuit, the second DC level adjusting circuit, the analog to digital converter, the sync signal processor and the multiplexer, for controlling the first DC level adjusting circuit, the second DC level adjusting circuit, and for generating the selecting signal.

The present invention also discloses a method for processing a video signal, which processes a data signal higher than a blanking level and a sync signal lower than the blanking level. The method comprises: (a) adjusting a DC level of the video signal to generate a first adjusted video signal; (b) separating the sync signal from the first adjusted video signal; (c) detecting if the sync signal exists; (d) sampling the video signal according to a predetermined clock signal to generate a first sampling result; (e) adjusting the video signal according to the first sampling result to generate a second adjusted video signal if the sync signal is detected in the step (c); (f) sampling the second adjusted video signal according to the predetermined clock signal to generate a second sampling result; (f) adjusting the first adjusted video signal according to the second sampling result to generate a third adjusted video signal; (g) detecting if there is a sync signal in the third video signal, if yes, sampling the second adjusted video signal according to a sync clock signal corresponding to the sync signal of the third adjusted video signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a transmitting path for transmission of a video signal.

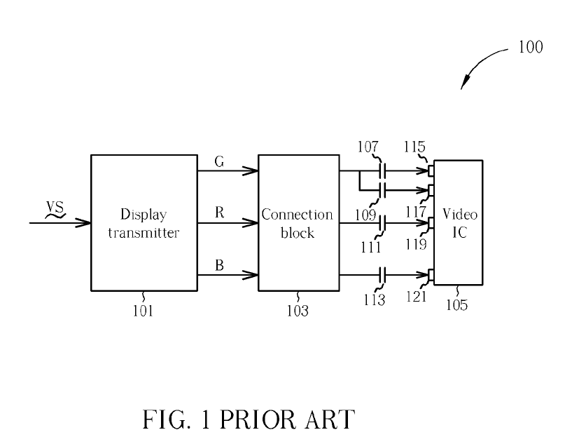

FIG. 2 is a related art video signal processing circuit.

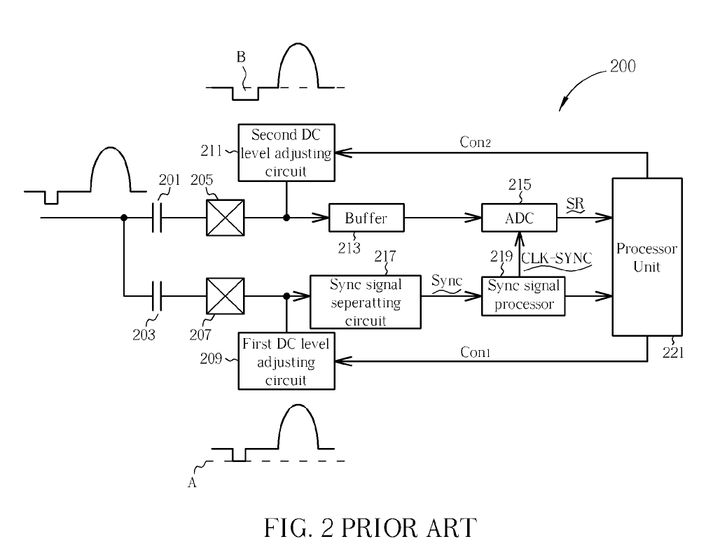

FIG. 3 is a video signal processing circuit according to a preferred embodiment of the present invention.

FIG. 4 is a schematic diagram illustrating operation of the sync signal separating circuit illustrated in FIG. 3.

FIG. 5 is a method for processing a video signal according to a preferred embodiment of the present invention.

FIG. 6 is a diagram illustrating different DC levels of the first and the second adjusted video signals in different time periods.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

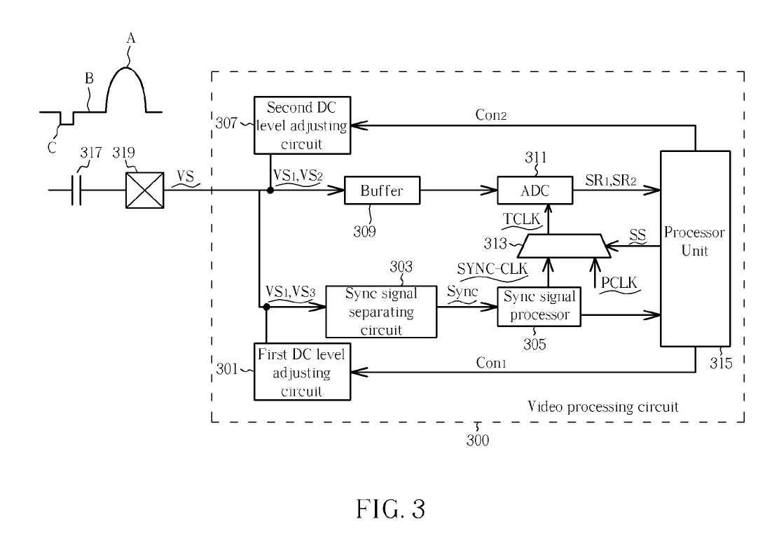

FIG. 3 is a video signal processing circuit 300 according to a preferred embodiment of the present invention. As shown in FIG. 3, the video signal VS comprises: a data signal A higher than a blanking level B, and a sync signal C lower than the blanking level B. The video signal processing circuit 300 includes: a first DC level adjusting circuit 301, a sync signal separating circuit 303, a sync signal processor 305, a second DC level adjusting circuit 307, a buffer 309, an analog to digital converter 311, a multiplexer 313 and a processor unit 315. The first DC level adjusting circuit 301, which is coupled to the video signal VS, is used for adjusting the DC level of the video signal VS to generate a first adjusted video signal VS₁, and for adjusting the DC level of the first video signal VS₁ to generate a third video signal VS₃. The second DC level adjusting circuit 307, which is coupled to the video signal VS, is used for adjusting a DC level of the video signal VS to generate a second adjusted video signal VS₂. It should be noted that if the video signal processing circuit 300 is located in a video IC (integrated circuit), then the video IC includes only one capacitance 317 and one pad 319. The first DC level adjusting circuit 301 and second DC level adjusting circuit 307 are jointly coupled to the pad 319, but this is not intended to limit the scope of the present invention.

The buffer 309, which is coupled between the second DC level adjusting circuit 307 and the analog to digital converter 311, is used for buffering the video signal VS and the second adjusted video signal VS₂. The analog to digital converter 311, which is coupled to the second DC level adjusting circuit 307, is used for sampling the data signal according to the second adjusted video signal VS₂, and a target clock signal TCLK. The sync signal separating circuit 303, which is coupled to the first DC level adjusting circuit 301, is used for separating the sync signal SYNC from the first adjusted video signal VS₁ and the third adjusted video signal VS₃. The sync signal processor 305, which is coupled to the sync signal separating circuit 303, is used for detecting the existence of the sync signal SYNC, and outputting a sync clock signal SYNC-CLK according to the sync signal SYNC if the sync signal processor 303 detects the existence of the sync signal SYNC. The multiplexer 313, which is coupled to the analog to digital converter 311 and the sync signal processor 305, is used for outputting one of the sync clock signal SYNC-CLK, and a predetermined clock signal PCLK, as the target clock signal TCLK according to a selecting signal SS. The processor unit 315, which is coupled to the first DC level adjusting circuit 301, the second DC level adjusting circuit 307, the analog to digital converter 311, the sync signal processor 305 and the multiplexer 313, controls the first DC level adjusting circuit 301, the second DC level adjusting circuit 307, and generates the selecting signal SS.

The above description is only describes the function of each device of the video signal processing circuit 300. Operation of the entire video signal processing circuit 300, will now be described below. This is not intended to limit the scope of the present invention however. People skilled in the art may use a similar structure with a different operation order to obtain the same functionality, which also falls within the scope of the present invention.

First, the predetermined clock PCLK is utilized as the target clock signal TCLK. The second DC level adjusting circuit 307 is initially turned off. The processor unit 315 controls the first DC level adjusting circuit 301 to adjust the DC voltage level of the video signal VS for generating the first adjusted video signal VS₁, such that the sync signal of the first adjusted video signal VS₁ can be separated from the first adjusted video signal VS₁. The analog to digital converter 311 samples the first adjusted video signal VS₁ according to the target clock signal TCLK to generate a first sampling result SR₁. At this time, a digital code corresponding to the blanking level B is obtained by the analog to digital converter 311. The digital code is sent to the processor unit 221. Then the sync signal processor 305 detects whether a valid sync signal SYNC exists. The sync signal processor 305 uses a first slicing level below the blanking level to detect the sync signal SYNC. After the sync signal processor 305 informs the processor unit 315 the existence of the sync signal SYNC, the processor unit 315 turns on the second DC level adjusting circuit 307 to adjust the video signal VS for the second adjusted video signal VS₂, and the analog to digital converter 311 samples the second adjusted video signal VS₂ according to the target clock signal TCLK to generate the second sampling result SR₂. In this case, the first sampling result SR₁ is just rough information for sampling the data signal. The second sampling result SR₂ is accurate information for sampling the data signal to obtain the correct video data.

However, the first slicing level is no longer accurate because the DC level of the first adjusted video signal VS₁ has been changed. The processor unit 315 informs the sync signal separating circuit 303 to adjust the first slicing level into a second slicing level. The second slicing level is able to correctly detect the sync signal SYNC. Then the sync signal separating circuit 303, separates the sync signal SYNC from the adjusted video signal VS₂, and the sync signal processor 305 generates the sync clock signal SYNC-CLK. The processor unit 315 is then informed of the existence of the sync clock signal SYNC-CLK. After that, the processor unit 315 generates the selecting signal SS to select the SYNC clock signal SYNC-CLK as the predetermined clock signal TCLK. Finally, the analog to digital converter 311 samples the second adjusted video signal VS2 according to the predetermined clock signal TCLK (the SYNC clock signal SYNC-CLK according to the adjusted video signal VS₂ ) to obtain the correct data. It should be noted that the buffer 309 can be omitted from the video signal processing circuit 300 if the analog to digital converter 311 can sample the first adjusted video signal VS₁ and the second adjusted video signal VS₂ accurately.

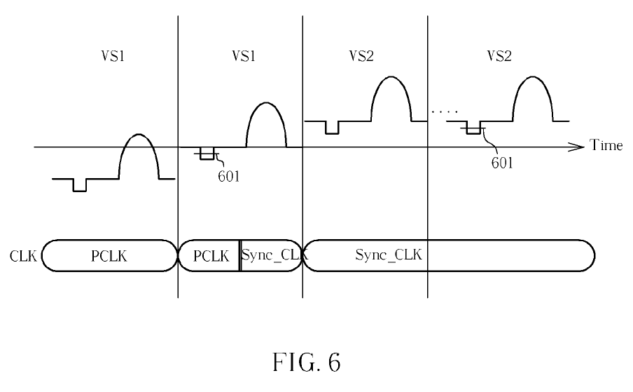

FIG. 6 is a diagram illustrating different DC levels of the first and the second adjusted video signals in different time periods. With reference to FIG. 6, in the time period 1, the video signal VS is not adjusted by the first DC level adjusting circuit 301 or the second DC level adjusting circuit 307. In the time period 2, the DC level of the video signal VS is adjusted into the first adjusted video signal VS₁. The sync signal separating circuit separates the sync signal SYNC from the first adjusted video signal by the first slicing level 601. The sync clock signal SYNC-CLK can also be obtained from the sync signal SYNC. Once the sync clock signal SYNC-CLK is obtained, the multiplexer 313 selects the sync clock signal as the target clock signal TCLK. In the beginning of the time period 2, the ADC 311 samples the first adjusted video signal VS₁ according to the predetermined clock to generate the first sampling result SR1. The processor unit 315 also obtains a digital code of the blanking level of the first adjusted video signal in the time period 2. In the time period 3, the first adjusted video signal VS₁ is further adjusted into the second adjusted video signal VS₂ to properly fit the input range of the ADC 311. However, the first slicing level 601 is not suitable for use in the second adjusted video signal VS₂. The processor unit 315 then controls the sync signal separating circuit 303 to adjust the first slicing level 601 into the second slicing level 603. Using the second slicing level 603, the sync signal separating circuit 303 can properly separate the sync signal SYNC from the second adjusted video signal VS₂.

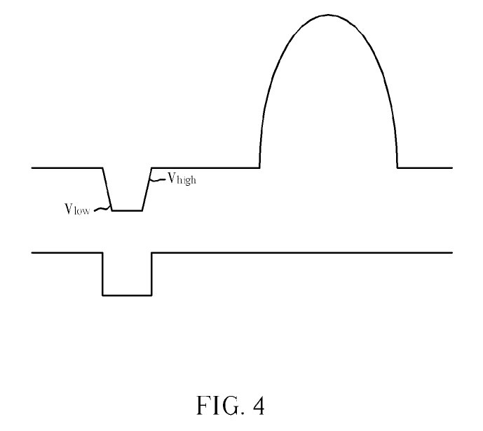

FIG. 4 is a schematic diagram illustrating operation of the sync signal separating circuit 303 as illustrated in FIG. 3. Another preferred embodiment of the sync signal separating circuit 303 is a well known circuit-smith trigger. Operation of the smith trigger is as shown in FIG. 4. The smith trigger utilizes a low voltage V_{low} and high voltage V_{high} as reference voltages to separate the sync signal from the video signal. Since operation and structure of the smith trigger is well known by persons skilled in the art, it is omitted for brevity.

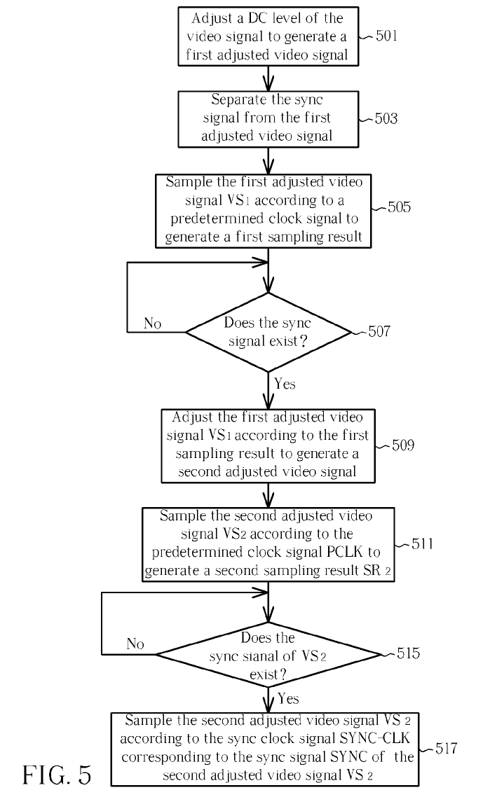

FIG. 5 is a method for processing a video signal according to a preferred embodiment of the present invention. The method corresponds to, but is not limited to the video processing circuit 300 as shown in FIG. 3. The method comprises:

### Step 501:

Adjust a DC level of the video signal VS to generate a first adjusted video signal VS₁.

### Step 503:

Separate the sync signal SYNC from the first adjusted video signal VS₁.

### Step 505:

Sample the first adjusted video signal VS₁ according to a predetermined clock signal PCLK to generate a first sampling result SR₁.

### Step 507:

Detect if the sync signal SYNC of the first adjusted video signal VS₁ exists. If yes, go to step 509, otherwise go back to step 507.

### Step 509:

Adjust the first adjusted video signal VS₁ according to the first sampling result SR₁ to generate a second adjusted video signal VS₂.

### Step 511:

Sample the second adjusted video signal VS₂ according to the predetermined clock signal PCLK to generate a second sampling result SR₂.

### Step 515:

Detect if the sync signal SYNC of the second adjusted video signal VS₂ exists. If yes, go to step 517, otherwise go back to the step 515.

### Step 517:

Sample the second adjusted video signal VS₂ according to the sync clock signal SYNC-CLK corresponding to the sync signal SYNC of the second adjusted video signal VS₂.

The method shown in FIG. 5 can further buffer the first adjusted video signal VS₁ to be sampled in the step 505, and the second adjusted signal to be sampled in the step 511. Also, it should be noted that step 505 is not necessarily performed after the step 503, it also could be performed before step 503.

According the above-mentioned circuit and method, two DC level adjusting circuits can be jointly coupled to one device for receiving the video signal. Therefore one pin of the video IC can be saved if the circuit and method are utilized for a video IC. The video processing circuit according to the preferred of the present invention can also be applied for other systems or apparatuses except the Video IC.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A video signal processing circuit, for processing a video signal having a data signal higher than a blanking level and a sync signal lower than the blanking level, the video signal processing circuit comprising:
a first DC level adjusting circuit, coupled to the video signal, for adjusting a DC level of the video signal to generate a first adjusted video signal};
a second DC level adjusting circuit, coupled to the video signal, for adjusting a DC level of the video signal to generate a second adjusted video signal;
an analog to digital converter, coupled to the second DC level adjusting circuit, for sampling the data signal according to the second adjusted video signal and a target clock signal;
a sync signal separating circuit, coupled to the first DC level adjusting circuit, for separating the sync signal from the first adjusted video signal;
a sync signal processor, coupled to the sync signal separating circuit, for detecting an existence of the sync signal, and outputting a sync clock signal according to the sync signal when the sync signal processor detects the existence of the sync signal;
a multiplexer, coupled to the analog to digital converter and the sync signal processor, for outputting one of the sync clock signal or a predetermined clock signal as the target clock signal according to a selecting signal; and
a processor unit, coupled to the first DC level adjusting circuit, the second DC level adjusting circuit, the analog to digital converter, the sync signal processor and the multiplexer, for controlling the first DC level adjusting circuit, the second DC level adjusting circuit, and for generating the selecting signal.

2. The video signal processing circuit of claim 1, wherein the first DC level adjusting circuit is initially turned on and controlled by the processor unit, the second DC level adjusting circuit is initially turned off, and the processor unit controls the multiplexer to initially select the predetermined clock signal as the target clock signal.

3. The video signal processing circuit of claim 2, wherein the analog to digital converter samples the first adjusted video signal to generate a first sampling result according to the predetermined clock signal, the processor unit adjusts the second DC level adjusting circuit according to the first sampling result, to adjust the first adjusted video signal to be the second adjusted video signal if the sync signal processor detects the existence of the sync signal.

4. The video signal processing circuit of claim 3, wherein the analog to digital converter further samples the second adjusted video signal according to the predetermined clock to generate a second sampling result.

5. The video signal processing circuit of claim 4, wherein the multiplexer selects the sync clock signal as the target clock signal if the sync signal processor detects the existence of the sync signal of the second adjusted video signal.

6. The video signal processing circuit of claim 1 applied to an integrated circuit, wherein the first DC level adjusting circuit and the second DC level adjusting circuit are both connected to a single pin of the integrated circuit for receiving the video signal.

7. The video signal processing circuit of claim 1, further comprising a buffer coupled between the second DC level adjusting circuit and the analog to digital converter, for buffering the first adjusted video signal and the second adjusted video signal to be sampled by the analog to digital converter.

8. The video signal processing circuit of claim 1, wherein the sync signal separating circuit is a smith trigger.

9. A method for processing a video signal having a data signal higher than a blanking level and a sync signal lower than the blanking level, the method comprising:
(a) adjusting a DC level of the video signal to generate a first adjusted video signal;
(b) separating the sync signal from the first adjusted video signal;
(c) detecting if the sync signal exists;
(d) sampling the first adjusted video signal according to a predetermined clock signal to generate a first sampling result;
(e) adjusting the first video signal to generate a second adjusted video signal if the sync signal is detected in step (c); and
(f) sampling the second adjusted video signal and generating a second sampling result according to the sync clock signal corresponding to the sync signal of the second adjusted video signal if there is a sync signal detected in the second video signal.

10. The method of claim 9, further comprising buffering the first adjusted video signal to be sampled in step (d), and buffering the second adjusted signal to be sampled in step (d).
